(19) United States
(12) Patent Application Publication
(10) Pub. No.: US 2008/0117608 A1
(43) Pub. Date: May 22, 2008

(54) Printed circuit board and fabricating method thereof

(75) Inventors: Ho-Seong Seo, Suwon-si (KR); Young-Min Lee, Yongin-si (KR); Shi-Yun Cho, Anyang-si (KR); Youn-Ho Choi, Suwon-si (KR); Sang-Hyun Kim, Yongin-si (KR)

Correspondence Address: CHA & REITER, LLC, 210 ROUTE 4 EAST STE 103, PARAMUS, NJ, 07652, US

(73) Assignee: Samsung Electronics Co., LTD.

(21) Appl. No.: 11/974,962

(22) Filed: Oct. 17, 2007

(30) Foreign Application Priority Data
Nov. 22, 2006 (KR) 2006-115676

(51) Int. Cl. H05K 1/18; H05K 1/02; H05K 3/10; H05K 3/42

(52) U.S. Cl. 361/761; 29/852

(57) ABSTRACT

Disclosed are a multi-layer PCB and a fabricating method thereof. The multi-layer PCB includes: a core; a plurality of insulation layers and a plurality of conductive pattern layers alternatively stacked on both sides of the core; and a plurality of via holes formed through the core and the insulation layers. The fabricating method may includes the steps of: forming a conductive pattern layer on each of both sides of a core, and forming via holes through the core; attaching a double-stick tape with weak adhesive strength to a portion of each of a upper surface and a lower surface of the core; and forming an insulation layer on each of a upper surface and a lower surface of the core to cover the double-stick tapes, and forming a conductive pattern layer on each of the insulation layers.

### CLAIM OF PRIORITY

This application claims the benefit under 35 U.S.C. §119(a) of an application entitled “Printed Circuit Board And Fabricating Method Thereof,” filed in the Korean Intellectual Property Office on Nov. 22, 2006 and assigned Serial No. 2006-115676, the contents of which are hereby incorporated by reference.

### BACKGROUND OF THE INVENTION

1. Field of the Invention

The present invention relates to a multi-layer printed circuit board (multi-layer PCB), and more particularly to a multi-layer PCB which has semiconductor dies (or integrated circuits) embedded (or seated) thereinside.

2. Description of the Related Art

PCBs are used in various types of electric products. Especially, the multi-layer PCB, which has a layered structure including insulation layers and conductive pattern layers stacked alternatively, is used in electronic devices requiring high-density integration, such as a notebook computer, a portable radiotelephone, etc.

FIG. 1A is a sectional view of a conventional multi-layer PCB. As shown, the multi-layer PCB 100 has a layered structure including a first to a fifth insulation layer 130, 112, 113, 122 and 123 and a first to an eighth conductive pattern layer 111a, 112a, 113a, 121a, 122a and 123a alternatively stacked. The multi-layer PCB includes a first and a second core 111 and 121 with dies 114 and 124 respectively, which are seated within the layered structure. The first and the second core 111 and 121 are attached to each other with the third insulation layer 130 disposed between them.

The first and the second semiconductor dies 114 and 124 are seated inside the multi-layer PCB 100 and have a plurality of bumps on their surface to electrically connect with outer components.

Since the bumps have very small pitch and size, there is a need to perform a re-routing process which includes displacing conductive pads in circuit areas of the first and the second semiconductor dies 114 and 124. That is to say, the re-routing process provides the first and the second semiconductor dies 114 and 124 with the conductive pads having a size bigger than the bumps so that electrical connections between the dies 114 and 124 and adjacent corresponding conductive pattern layers are more easily achieved.

The multi-layer PCB 100 has a plurality of via holes 111b, 112b, 113b, 121b, 122b and 123b for interlayer electrical connections, through which two neighboring conductive pattern layers 111a, 112a, 113a, 121a, 122a and 123a are electrically connected with each other. The via holes 111b, 112b, 113b, 121b, 122b and 123b may be formed by laser etching or the like.

Electrical interconnections between the first semiconductor 114 and the second semiconductor die 114, and between the conductive pattern layer 111a and the conductive pattern layer 121a are also made through the via holes 111b and 121b respectively. That is to say, the first and the second semiconductor die 114 and 124 can be connected with each other through the via hole 121b formed through the first core 111, the third insulation layer 130, and the second core 121.

FIG. 1B is a sectional view illustrating the laser etching, by which a portion of the first core 111 is etched so as to seat the first semiconductor die 114. FIG. 1C is a plan view illustrating a laser light path of a laser device 102 shown in FIG. 1B. When etching the portion of the first core 111 by laser device 102, as shown in FIG. 1C, the laser light should be radiated to the portion to be etched in a predetermined pattern.

The above described multi-layer PCB(100), which is a coupled structure of two individual PCBs 110 and 120, has a problem in that since the via hole 121b is formed to penetrate the cores 111, 130 and 121, and the diameter of the via holes 121b is larger than that of other via holes 111b, 112b, 113b, 122b and 123b. That is to say, under the condition of the same area, the increasing diameter of the via holes of the conventional multi-layer PCB puts restrictions on a routing wiring.

Further, since two or more cores are attached to each other, there is a problem in that the conventional multi-layer PCB is limited to be applied to slim products.

### SUMMARY OF THE INVENTION

Accordingly, the present invention has been made to solve the above-mentioned problems occurring in the prior art and provides additional advantages, by providing a PCB capable of achieving a multi-layer structure with a thinner thickness.

Also, the present invention provides a PCB, which allows a wiring structure to be simplified.

According to one aspect of the present invention, there is provided a PCB which includes: a core; a plurality of insulation layers and a plurality of conductive pattern layers alternatively stacked on each of both sides of the core; and a plurality of via holes formed through the core and the insulation layers.

According to another aspect of the present invention, there is provided a method for fabricating a PCB, includes the steps of: forming a conductive pattern layer on each of both sides of a core, and forming via holes through the core; attaching a double-stick tape with weak adhesive strength to a portion of each of a upper surface and a lower surface of the core; and forming an insulation layer on each of a upper surface and a lower surface of the core to cover the double-stick tapes, and forming a conductive pattern layer on each of the insulation layers.

According to still another aspect of the present invention, there is provided a method for fabricating a PCB which includes the steps of: forming a conductive pattern layer on each of both sides of a core, and forming via holes through the core; attaching a double-stick tape with weak adhesive strength to a portion of a upper surface of the core; forming an insulation layer on each of a upper surface and a lower surface of the core, forming a conductive pattern layer on each of the insulation layers; forming a cavity by partially removing the insulation layer formed on the upper surface of the core; seating a semiconductor die within the cavity formed by partially removing the insulation layer; and alternatively forming at least an insulation layer and at least a conductive pattern layer on each of the insulation layers.

### BRIEF DESCRIPTION OF THE DRAWINGS

The above and other aspects, features and advantages of the present invention will be more apparent from the following detailed description taken in conjunction with the accompanying drawings, in which:

FIG. 1A is a sectional view of a conventional multi-layer PCB;

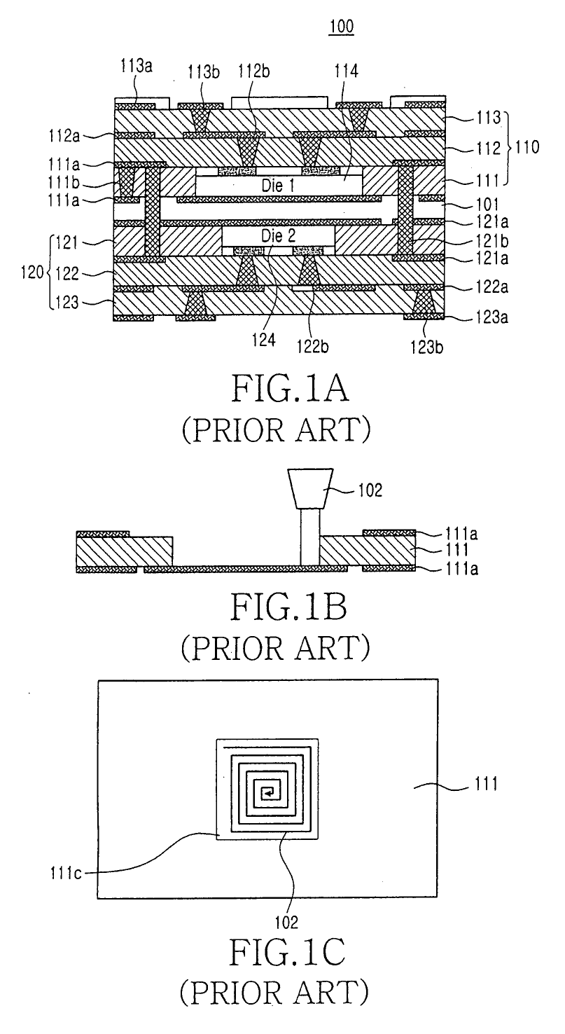

FIGS. 1B and 1C are views illustrating laser etching of an insulation layer included in multi-layer PCB of FIG. 1 for seating of a semiconductor die;

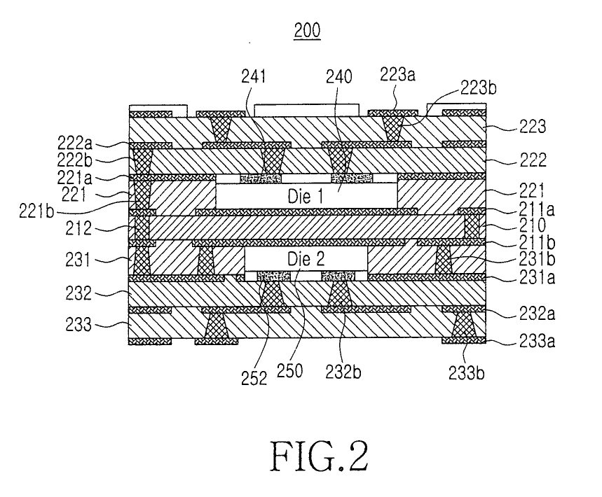

FIG. 2 is a sectional view of a multi-layer PCB in accordance with an exemplary embodiment of the present invention;

FIGS. 3A to 3E are sectional views illustrating the steps of a method for fabricating the multi-layer PCB shown in FIG. 2;

FIGS. 4A to 4C are sectional views illustrating the steps of a method for fabricating the multi-layer PCB according to another embodiment of the present invention; and

FIG. 5 is a schematic plan view illustrating laser etching of an insulation layer shown in FIG. 4b for forming a cavity.

### DETAILED DESCRIPTION OF THE EXEMPLARY EMBODIMENTS

Hereinafter, exemplary embodiments of the present invention will be described with reference to the accompanying drawings. For the purposes of clarity and simplicity, a detailed description of known functions and configurations incorporated herein will be omitted as it may make the subject matter of the present invention unclear.

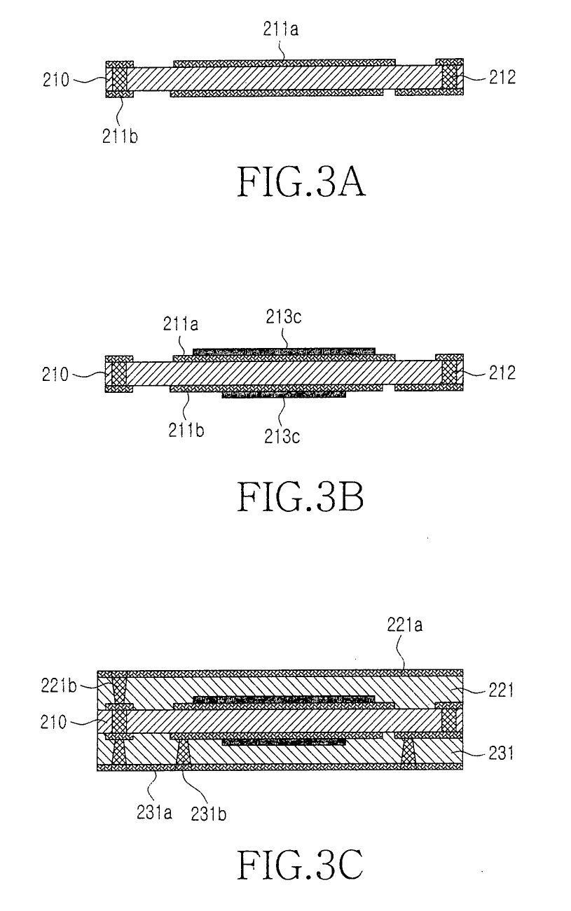

FIG. 2 is a sectional view of a multi-layer PCB in accordance with an exemplary embodiment of the present invention. As shown, the multi-layer PCB 200 of the present invention includes a core 210, a plurality of insulation layers 221-223 and 231-133 and a plurality of conductive pattern layers 211a, 211b, 221a, 222a, 223a, 231a, 232a, and 233a alternatively formed on each of both sides of the core 210, a plurality of via holes 212, 221b, 222b, 223b, 231b, 232b and 233b formed through the core 210 and the insulation layers 221-223 and 231-133, and first and second semiconductor dies 240 and 250.

The via holes 212, 221b, 222b, 223b, 231b, 232b and 233b are filled up with conductive filler material, thus allowing the conductive pattern layers 211a, 211b, 221a, 222a, 223a, 23 1a, 232a, and 233a displaced between insulation layers 221-223 and 231-233 to be electrically interconnected.

The first and second semiconductor dies 240 and 250 are seated on a top side and an under side of the core 210, respectively, so as to be embedded inside the multi-layer PCB 200. The first and second semiconductor dies 240 and 250 have at least an external connection terminal 241 and 252 for an external electrical connection on their surfaces, respectively. The external connection terminal 241 and 252 can be made by a re-routing process in which conductive pads are displaced in a circuit area of each of the semiconductor dies 240 and 250. That is to say, by the rerouting process, the external connection terminal 241 and 252 can be easily connected with an adjacent corresponding conductive pattern layer 222a and 231a, respectively.

The core 210 may be of a certain insulation material. On each of both sides of the core 210, the conductive pattern layers 211a, 211b, 221a,222a, 223a, 231a, 232a and 233a and the insulation layers 221-223 and 231-233 are alternatively formed. The conductive pattern layer 211a and 211b formed on a upper surface and a lower surface of the core 210 can be electrically interconnected with each other through the via holes 212 formed through the core 210. Since the semiconductor dies 240 and 250 are mounted on both sides of the core 210 respectively, the multi-layer PCB according to the present invention can be made using one core 210.

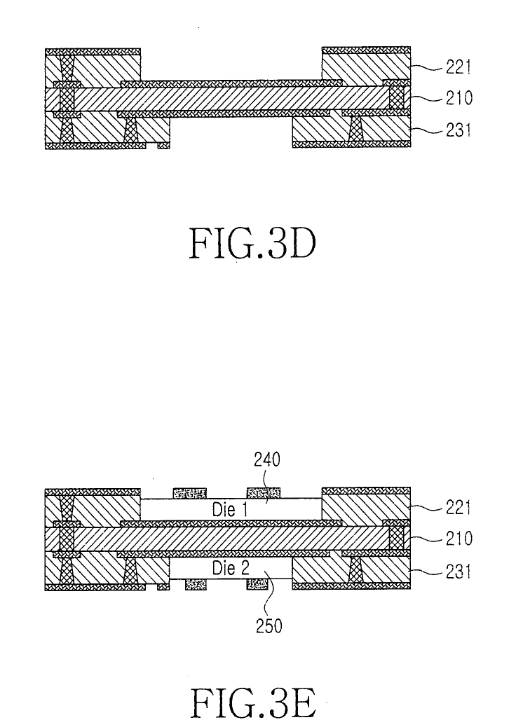

FIGS. 3A to 3E are views for illustrating a method for fabricating the multi-layer PCB 200 shown in FIG. 2. The method of fabricating the multi-layer PCB according to the present invention will now be described with reference to FIGS. 3A to 3E.

FIG. 3A is a view illustrating a state in which conductive pattern layers 211a and 211b and via holes 212 are formed on the core 210. The conductive pattern layer 211a and 211b are formed on both sides of the core 210, respectively, and are electrically interconnected with each other through the via holes 212.

FIG. 3B is a view illustrating a state in which each of double-stick tapes 213c having a weak adhesive strength is attached to a portion of each of a upper surface and lower surface of the core 210. Each of the double-stick tapes is attached only to a region on each of the upper surface and lower surface of the conductive pattern layer 221 and 231, where the semiconductor dies 240 and 250 are to be seated therein respectively.

FIG. 3C is a view illustrating a state in which insulation layers 221 and 231 are formed on the core 210 having the double-stick tapes attached thereto, and then conductive pattern layers 221a and 231a are formed on the insulation layers 221 and 231, respectively. Via holes 221b and 231b are formed through each of the insulation layers 221 and 231, through which the conductive pattern 221a and 231a can be interconnected with each other. The conductive pattern layer 221a and 231a may be formed in a pattern in which regions, in which the semiconductor dies 240 and 250 are to be seated respectively, are removed, so that laser etching can be easily carried out.

FIG. 3D is a view illustrating a state in which cavities are formed by removing portions of the insulation layer 221 and 231 over the double-stick tapes, which are formed on the upper surface and lower surface of the core 210. FIG. 3E is a view illustrating a state in which the first and second semiconductor dies 240 and 250 are seated within each of the cavities respectively.

By alternatively forming at least an insulation layer and at least a conductive pattern layer over each of the insulation layer 221 and 231 within which each of the first and second semiconductor die 240 and 250 is seated, the multi-layer PCB 200 shown in FIG. 2 can be accomplished.

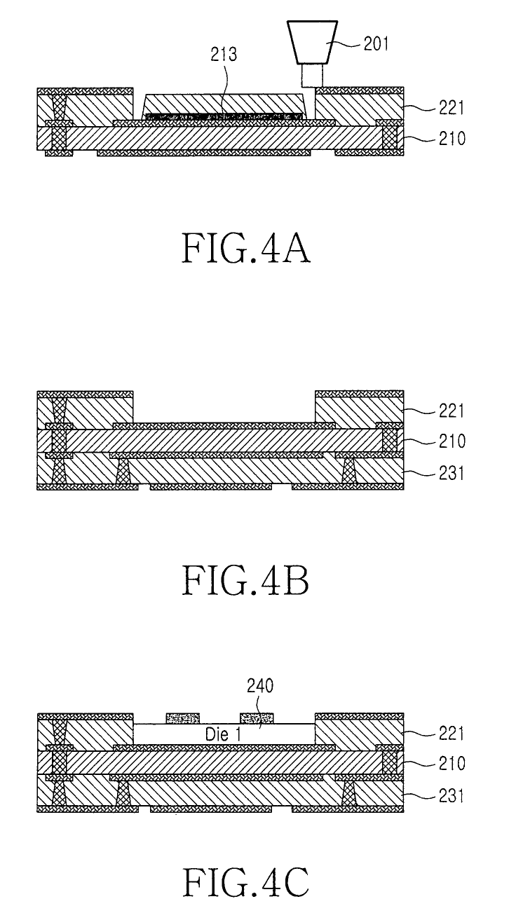

FIGS. 4A to 4C are sectional views illustrating a method for fabricating a multi-layer PCB according to another embodiment of the present invention, in which the processes of forming the via holes 212 through the core 210 and forming the conductive pattern layer 211a on the core 210 etc., are the same as those of FIGS. 3A to 3C. In the method for fabricating PCB according to this embodiment, the semiconductor die 240 is seated only to one side of the core 210.

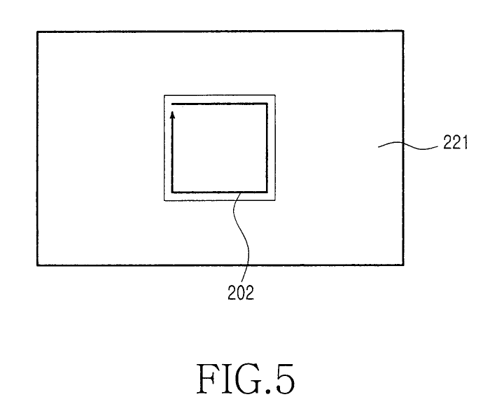

That is to say, according to this embodiment, as same as shown in FIGS. 3A to 3C, the conductive pattern layer is formed on each of both sides of the core 210, and the via holes are formed through the core 210. However, as shown in FIG. 4A, this embodiment differs from the processes of FIGS. 3D and 3E in that only the insulation layer 221 formed on the upper surface of the core 210 is partially removed to form a cavity for seating of the semiconductor die. As shown in FIG. 5, the outline of a portion of the insulation layer 221 to which the double-stick tape 213 is attached, is etched by means of laser device 201. Namely, by applying laser light of the laser device 201 to the outline 202 of the portion of the insulation layer 221 attached to the core by the double-stick tape 213, the cavity can be formed. Since the laser light is applied just along the outline of the portion of the insulation layer to which the double-stick tape 213 is attached, the semiconductor die to be seated is easily aligned.

FIG. 4B is a view illustrating a state in which the insulation layer 221 is partially removed by the means of laser device 101 shown in FIG. 4A to form the cavity. FIG. 4C is a view illustrating a state in which the semiconductor die 240 is seated within the cavity. By further alternatively forming at least an insulation layer and at least a conductive pattern layer on each of the insulation layer 221 and the insulation layer 23 1 formed on the upper surface and lower surface of the core 210 respectively, the PCB as shown in FIG. 4C can be accomplished.

The present invention has advantages in that since the individual PCBs are formed on both sides of one core, the fabricating process of the structure of the multi-layer PCB is simplified, and the multi-layer PCB has a thinner profile.

Further, according to the present invention, since the conductive pattern layers can be interconnected together through the via holes formed through the one core, a wiring structure can be easily simplified. The structure using the one core allows the via holes to be smaller, and thus high-density conductive pattern layers can be formed.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A PCB comprising:
a core;
a plurality of insulation layers and a plurality conductive pattern layers alternatively stacked on each of both sides of the core; and
a plurality of via holes formed through the core and the insulation layers.

2. The PCB as claimed in claim 1, wherein the via holes are filled up with a conductive filler material.

3. The PCB as claimed in claim 1, further comprising a first semiconductor die seated on an upper surface of the core so as to be embedded inside the PCB.

4. The PCB as claimed in claim 1, further comprising a second semiconductor die seated on a lower surface of the core so as to be embedded inside the PCB.

5. The PCB as claimed in claim 3, wherein the first semiconductor die has at least one external connection terminal for external electric connection on an upper surface thereof.

6. The PCB as claimed in claim 4, wherein the second semiconductor die has at least one external connection terminal for external electric connection on its upper surface.

7. A PCB comprising:
a core;
a plurality of insulation layers and a plurality of conductive pattern layers alternatively stacked on each of both sides of the core;
a plurality of via holes formed through the core and the insulation layers and filled up with a conductive filler material;
a first semiconductor die seated on a upper surface of the core to be embedded inside the PCB; and
a second semiconductor die seated on a lower surface of the core to be embedded inside the PCB.

8. A method for fabricating a PCB, comprising the steps of:
forming a conductive pattern layer on each of both sides of a core and forming via holes through the core;
attaching a double-stick tape having a weak adhesive strength to a portion of each of a upper surface and a lower surface of the core; and
forming insulation layers on each of the upper surface and the lower surface to cover the double-stick tapes and forming a conductive pattern layer each between the insulation layers.

9. The method for fabricating the PCB as claimed in claim 8, further comprising the steps of:
forming cavities by removing a portion of each of insulation layers formed on the double-stick tapes of the insulation layers formed on the upper surface and a lower surface of the core;
seating a semiconductor die within each of the cavities formed on the insulation layers on the upper surface and the lower surface of the core; and
alternatively forming at least one insulation layer and at least one conductive pattern layer on each of the insulation layers within which semiconductor die is seated.

10. A method for fabricating a PCB, comprising the steps of:
forming a conductive pattern layer on each of both sides of a core and forming via holes through the core;
forming an insulation layer on each of a upper surface and a lower surface of the core and forming a conductive pattern layer on each of the insulations;
forming a cavity by partially removing the insulation layer formed on the upper surface of the core;
seating a semiconductor die within the cavity formed by partially removing the insulation layer; and
alternatively forming at least one insulation layer and at least one conductive pattern layer on each of the insulation layers.
